(19) United States
(12) Patent Application Publication
(10) Pub. No.: US 2025/0287651 A1
(43) Pub. Date: Sep. 11, 2025

(54) SEMICONDUCTOR DEVICE AND METHOD OF MANUFACTURING THE SAME

(71) Applicant: TAIWAN SEMICONDUCTOR MANUFACTURING COMPANY, LTD., Hsinchu (TW)

(72) Inventors: Yang-Hsin SHIH, Hsinchu (TW); You-Cheng XIAO, Hsinchu (TW); Pin-Dai SUE, Hsinchu (TW)

(21) Appl. No.: 18/756,057

(22) Filed: Jun. 27, 2024

Related U.S. Application Data
(60) Provisional application No. 63/562,458, filed on Mar. 7, 2024.

(51) Int. Cl. H01L 29/06; H01L 29/423; H01L 29/66; H01L 29/775; H01L 29/786

(52) U.S. Cl. CPC H10D 62/10; H10D 30/014; H10D 30/43; H10D 30/6735; H10D 30/6757; H10D 62/121

(57) ABSTRACT

A semiconductor device and a method of manufacturing the same are provided. The semiconductor device includes a first type active region structure and a second type active region structure extending along a first direction. The semiconductor device also includes a first S/D contact over the first type active region structure and extending along a second direction different from the first direction. The semiconductor device further includes a backside conductive layer under the first type active region structure. In addition, the semiconductor device includes a backside interconnection structure between the backside conductive layer and the first type active region structure. The backside interconnection structure includes a first portion between the backside conductive layer and the first type active region structure, a second portion between the backside conductive layer and the second type active region structure, and a third portion connecting the first portion and the second portion.

### CROSS-REFERENCE TO RELATED APPLICATION(S)

This application claims the benefit of U.S. Provisional Application No. 63/562,458, filed Mar. 7, 2024, the entire disclosure of which is incorporated by reference herein.

### BACKGROUND

Currently, semiconductor devices are widely used in various fields, such as cloud storage, medicine, transportation, mobile devices, etc. The current trend in some aspects of semiconductor device manufacturing focuses on providing semiconductor devices with smaller dimensions and better power efficiency. It is therefore desirable to continuously improve the structure and manufacturing of the semiconductor devices.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A and FIG. 1B are layout diagrams of a semiconductor device, in accordance with some embodiments.

FIG. 2A, FIG. 2B, and FIG. 2C are cross-sectional views of the semiconductor device as specified by the layout diagrams in FIGS. 1A-1B, in accordance with some embodiments.

FIG. 3 is a cross-sectional view of a semiconductor device in accordance with some embodiments.

FIG. 4 is a cross-sectional view of a semiconductor device in accordance with some embodiments.

FIG. 5 is a layout diagram of a semiconductor device, in accordance with some embodiments.

FIG. 6 is a layout diagram of a semiconductor device, in accordance with some embodiments.

FIG. 7 is a layout diagram of a semiconductor device, in accordance with some embodiments.

FIG. 8 is a perspective view of a semiconductor device in accordance with some embodiments.

FIG. 9A, FIG. 9B, and FIG. 9C are cross-sectional views of the semiconductor device as shown in FIG. 8, in accordance with some embodiments.

FIG. 10 and FIG. 11 are flowcharts of a method for manufacturing a layout of a semiconductor device according to various aspects of the present disclosure.

FIG. 12 is a block diagram of a system of designing a semiconductor device, in accordance with some embodiments.

FIG. 13 is a block diagram of a semiconductor device manufacturing system, and a semiconductor device flow associated therewith, in accordance with some embodiments.

FIG. 14 is a flowchart of a method for manufacturing a semiconductor device, in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

This present disclosure generally relates to semiconductor devices, and more particularly to semiconductor devices with a backside interconnection structure (or a backside via). The backside interconnection structure includes fingers and a main portion connecting the fingers, enhancing the overlap area between the backside interconnection structure and a backside conductive layer (or backside power rail). This results in a decrease in resistance for transmitting power.

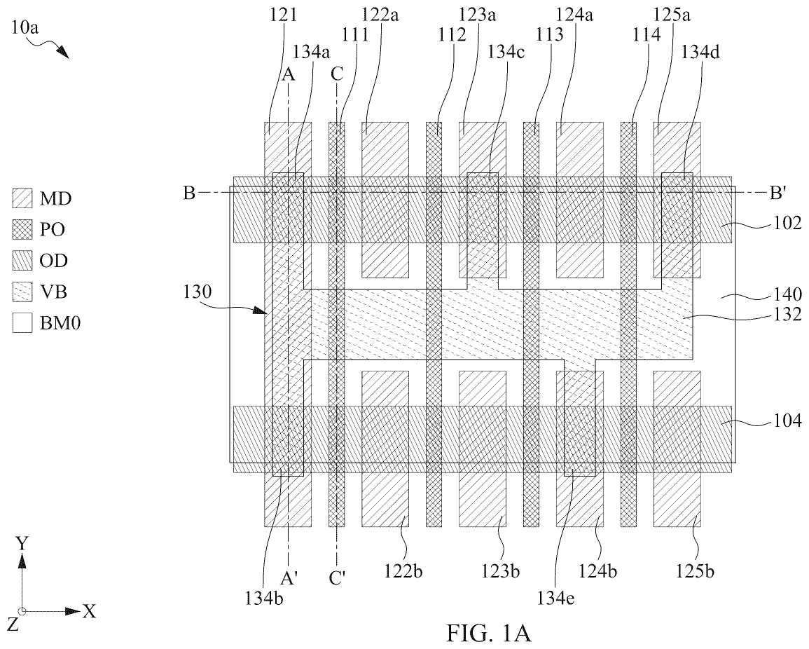

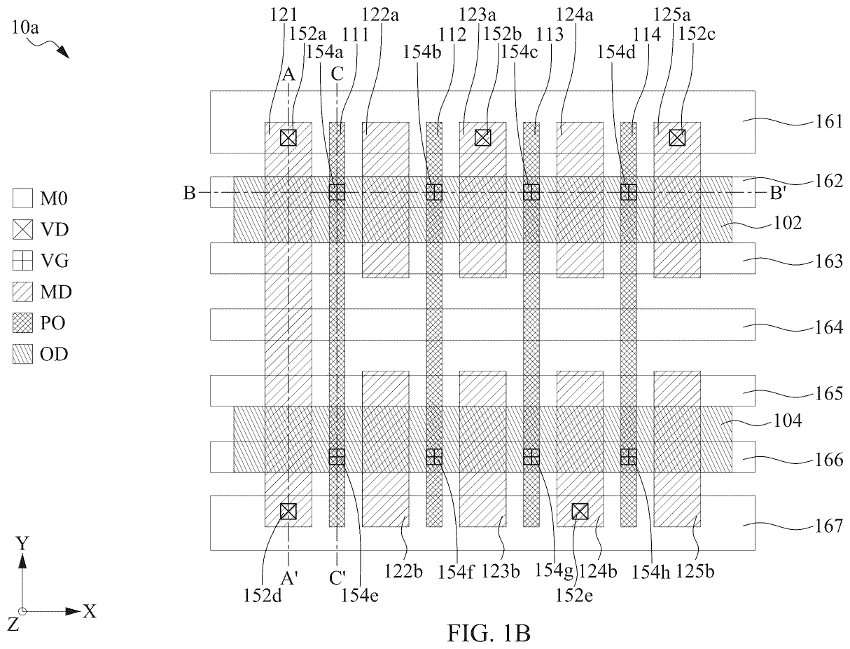

FIG. 1A and FIG. 1B are layout diagrams of a semiconductor device 10a in accordance with some embodiments. FIG. 1A includes the layout patterns for specifying the backside conductive features, and FIG. 1B includes the layout patterns for specifying the front-side conductive features.

Referring to FIG. 1A, the semiconductor device 10a includes active-region structures 102 and 104. Each of the active-region structures 102 and 104 extends along the X direction. In some embodiments, the active-region structure 102 includes a p-type active-region structure, and the active-region structure 104 includes an n-type active-region structure. Non-limiting examples of the active-region structures 102 and 104 include fin field-effect transistor (FinFETs), nano-sheet transistors, and nano-wire transistors. In some embodiments, the active-region structure 102 is spaced apart from the active-region structure 104 by an isolation structure (not shown), such as a shallow trench isolation (STI). In some embodiments, the active-region structures 102 and 104 can be referred to as an oxide definition region (also referred to as “OD”).

The semiconductor device 10a includes gate structures 111, 112, 113, and 114. Each of the gate structures 111 to 114 extends along the Y direction. The gate structures 111 to 114 intersect the active-region structure 102 at the channel region of a p-type transistor, and intersect the active-region structure 104 at the channel region of an n-type transistor. The gate structures 111 to 114 are disposed on a front-side of a substrate. In some embodiments, the gate structures 111 to 114 can be referred to as poly (PO) of a semiconductor device.

The semiconductor device 10a includes contacts 121, 122a, 122b, 123a, 123b, 124a, 124b, 125a, and 125b. Each of the contacts 121, 122a to 125a and 122b to 125b extends along the Y direction. The contacts 121 and 122a to 125a intersect the active-region structure 102 at a source/drain (S/D) region of a p-type transistor. The contacts 121 and 122b to 125b intersect the active-region structure 104 at a source/drain region of an n-type transistor. Each of the contacts 121, 122a to 125a and 122b to 125b are disposed on a front-side of a substrate. In some embodiments, the contacts 121, 122a to 125a and 122b to 125b can be referred to as metal diffusion (MD) conductive features of a semiconductor device. In some embodiments, each of the contacts 121, 122a to 125a and 122b to 125b corresponds to a source/drain contact of a semiconductor device.

The semiconductor device 10a includes a backside interconnection structure 130. In some embodiments, the backside interconnection structure 130 is interposed between the active regions (e.g., the active-region structures 102 and 104) and a backside power rail (e.g., backside conductive layer 140). In some embodiments, the backside interconnection structure 130 is electrically connected to some of the contacts 121, 122a to 125a and 122b to 125b for transmitting a power signal. In some embodiments, the backside interconnection structure 130 can be referred to as a backside via (VB).

In some embodiments, the backside interconnection structure 130 includes a main portion 132 extending along the X direction. In some embodiments, the main portion 132 is disposed between the active-region structures 102 and 104 in a top view. In some embodiments, the main portion 132 is free from overlapping the active-region structures 102 and 104 along the Z direction. In some embodiments, the main portion 132 is disposed between two source/drain contacts (e.g., contacts 122a and 122b) in a top view. In some embodiments, the main portion 132 overlaps the contact 121 along the Z direction and is connected to the contact 121.

In some embodiments, the backside interconnection structure 130 includes fingers 134a, 134b, 134c, 134d, and 134e protruding from the main portion 132. The fingers 134a to 134e are configured to be connected to a source/drain contact for transmitting a power signal. In some embodiments, each of the fingers 134a to 134e extends along the Y direction. The fingers 134a, 134c, and 134d overlap the active-region structure 102 along the Z direction. The fingers 134b and 134e overlap the active-region structure 104 along the Z direction. In some embodiments, the fingers 134a and 134b overlap the contact 121 along the Z direction and are connected to the contact 121. The finger 134c overlaps the contact 123a along the Z direction and is connected to the contact 123a. The finger 134d overlaps the contact 125a along the Z direction and is connected to the contact 125a. The finger 134e overlaps the contact 124b along the Z direction and is connected to the contact 124b. In some embodiments, the finger 134a is connected to the finger 134b through the main portion 132. Although FIG. 1A illustrates that the backside interconnection structure 130 includes five fingers, it should be noted that the backside interconnection structure 130 can include more or fewer fingers based on the design requirements.

In some embodiments, each of the main portion 132 (or a part of the main portion 132) and fingers 134a to 134e can be regarded as a sub-region of the backside interconnection structure 130.

In some embodiments, the semiconductor device 10a includes a backside conductive layer 140. The backside conductive layer 140 may be disposed on a backside of a substrate. The backside conductive layer 140 may be connected to the backside interconnection structure 130. In some embodiments, the backside conductive layer 140 can be referred to as a first backside metal (BMO). The backside conductive layer 140 may be a power rail for providing electric power to the corresponding source/drain feature that is connected to the backside interconnection structure 130. In some embodiments, the backside conductive layer 140 at least partially overlaps the active-region structures 102 and 104 along the Z direction. In some embodiments, the backside conductive layer 140 overlaps the main portion 132 at a region between the active-region structures 102 and 104 in a top view.

Referring to FIG. 1B, the semiconductor device 10a includes vias 152a, 152b, 152c, 152d, and 152e. The vias 152a and 152d overlap the contact 121 along the Z direction and are connected to the contact 121. The via 152b overlaps the contact 123a along the Z direction and is connected to the contact 123a. The via 152c overlaps the contact 125a along the Z direction and is connected to the contact 125a. The via 152e overlaps the contact 124b along the Z direction and is connected to the contact 124b. In some embodiments, each of the vias 152a to 152e can be referred to as “VD.”

The semiconductor device 10a includes vias 154a, 154b, 154c, 154d, 154e, 154f, 154g, and 154h. The vias 154a and 154e overlap the gate structure 111 along the Z direction and are connected to the gate structure 111. The vias 154b and 154f overlap the gate structure 112 along the Z direction and are connected to the gate structure 112. The vias 154c and 154g overlap the gate structure 113 along the Z direction and are connected to the gate structure 113. The vias 154d and 154h overlap the gate structure 114 along the Z direction and are connected to the gate structure 114. In some embodiments, the vias 154a to 154h can be referred to as “VG.”

The semiconductor device 10a includes front-side conductive layers 161, 162, 163, 164, 165, 166, and 167. Each of the front-side conductive layers 161 to 167 extends along the X direction. In some embodiments, the front-side conductive layers 161 to 167 may be configured for being electrically connected to the contacts 121 to 125b and/or gate structures 111 to 114. In some embodiments, the front-side conductive layers 161 and 167 are configured for providing a supply voltage. For example, the front-side conductive layer 161 may be connected to the contact 121 by the via 152a, and the front-side conductive layer 167 may be connected to the contact 121 by the via 152d. The front-side conductive layers 162 to 166 are configured for transmitting, for example, signals (e.g., input and/or out signals). In some embodiments, some of the front-side conductive layers 162 to 166 may function as dummy tracks which are not connected to the contacts 121 to 125b and gate structures 111 to 114. The profiles of the front-side conductive layers 162 to 166 can be modified based on the design requirements. In some embodiments, the front-side conductive layers 161 to 167 can be referred to as “M0.”

In some embodiments of the disclosure, the backside interconnection structure 130 includes the main portion 132 connected to the fingers 134a to 134e. The main portion 132 is configured to enhance the overlapping area between the backside interconnection structure 130 and the backside conductive layer 140, which results in a reduction in the resistance for transmitting power.

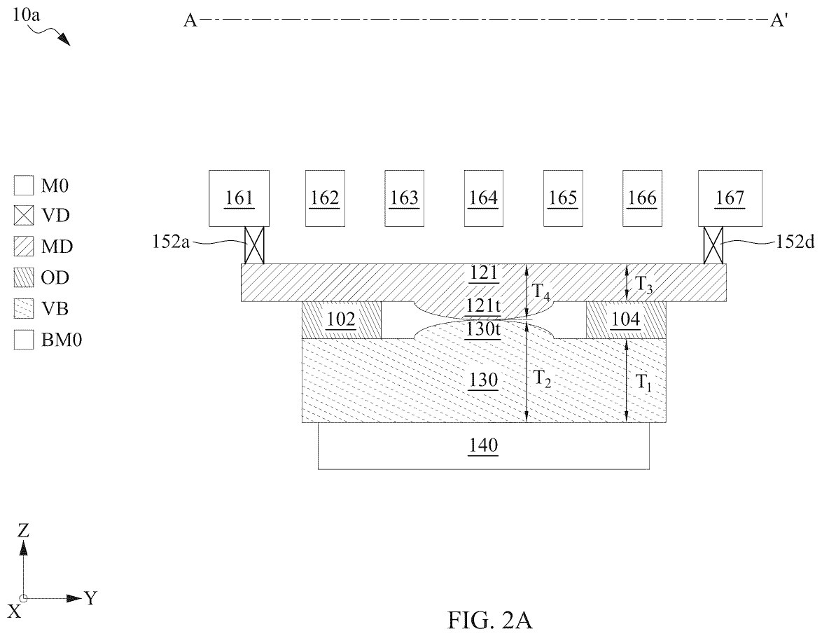

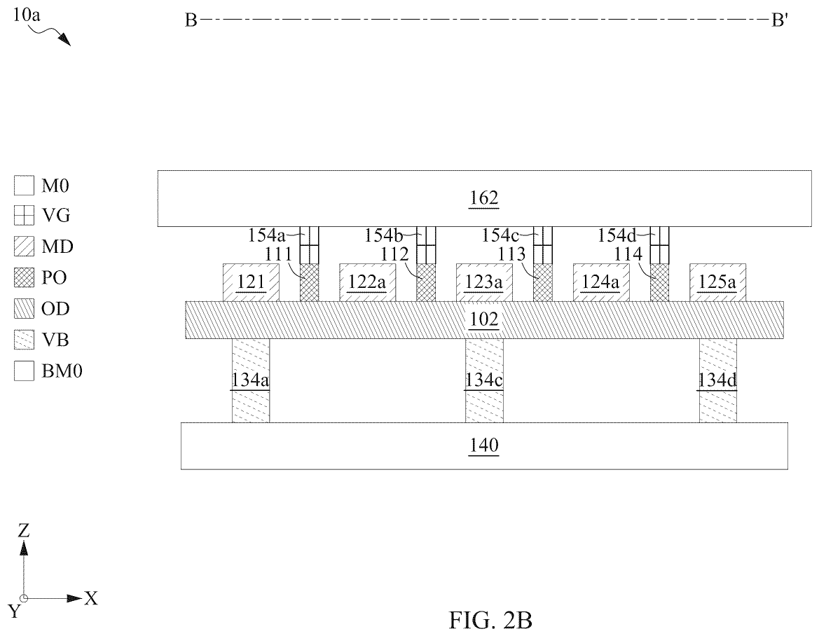

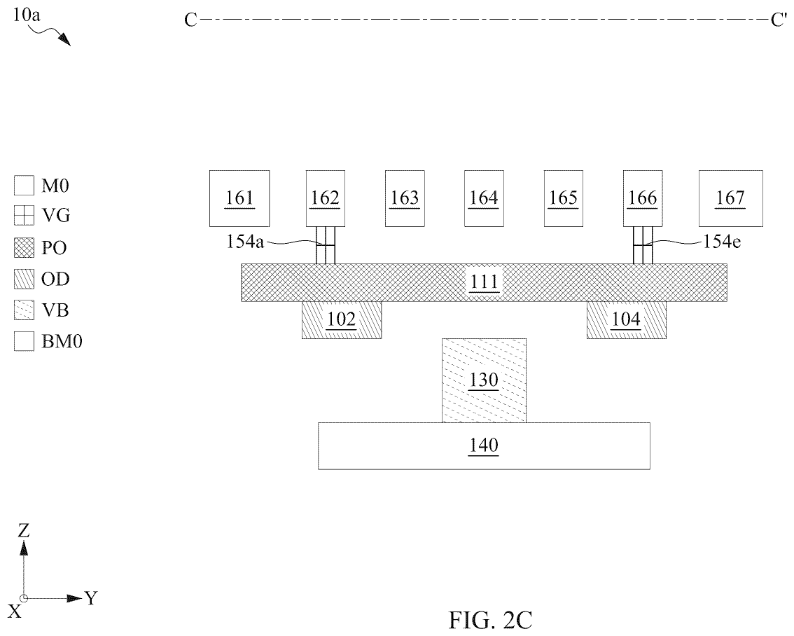

FIG. 2A, FIG. 2B, and FIG. 2C are cross-sectional views along lines A-A′, B-B′, and C-C′ of FIGS. 1A-1B, respectively. It should be noted that FIGS. 2A-2C merely illustrate the features shown in FIGS. 1A-1B, and some features, such as a substrate, dielectric layers, isolation structures and/or other elements, are omitted for brevity.

Referring to FIG. 2A, the contact 121 is disposed over the active-region structures 102 and 104. The front-side conductive layer 161 is disposed over and electrically connected to the contact 121 by the via 152a. The front-side conductive layer 167 is disposed over and electrically connected to the contact 121 by the via 152d. The backside interconnection structure 130 is disposed between the active-region structure 102 and the backside conductive layer 140 as well as between the active-region structure 104 and the backside conductive layer 140. The backside conductive layer 140 is disposed under the backside interconnection structure 130. The backside conductive layer 140 is connected to the active-region structures 102 and 104 by the backside interconnection structure 130. In some embodiments, the contact 121 includes a protruding portion 121t. The protruding portion 121t is disposed between the active-region structures 102 and 104. The protruding portion 121t protrudes toward the backside interconnection structure 130. In some embodiments, the protruding portion 121t includes a curved lower surface or boundary. In some embodiments, the backside interconnection structure 130 includes a protruding portion 130t. The protruding portion 130t is disposed between the active-region structures 102 and 104. The protruding portion 130t protrudes toward the contact 121. In some embodiments, the protruding portion 130t includes a curved upper surface or boundary. In some embodiments, the protruding portion 121t is in contact with the protruding portion 130t and builds an interface between the contact 121 and the backside interconnection structure 130. The backside interconnection structure 130 has a first portion, under the active-region structure 102 (or active-region structure 104) with a thickness T₁. The backside interconnection structure 130 has a second portion, in contact with the contact 121, with a thickness T₂. In some embodiments, the thickness T₂ is greater than the thickness T₁. The contact 121 has a first portion, over the active-region structure 102 (or active-region structure 104) with a thickness T₃. The contact 121 has a second portion, in contact with the backside interconnection structure 130, with a thickness T₄. In some embodiments, the thickness T₄ is greater than the thickness T₃. In some embodiments, the protruding portion 121t and the protruding portion 130t are configured to add a linkage between the backside interconnection structure 130 and the contact 121, which results in a decrease in electrical resistance.

Referring to FIG. 2B, the fingers 134a, 134c, and 134d are disposed under the active-region structure 102. The fingers 134a, 134c, and 134d are connected to the backside conductive layer 140. The fingers 134a, 134c, and 134d are disposed between the active-region structure 102 and the backside conductive layer 140. The gate structures 111 to 114 are disposed over the active-region structure 102. The vias 154a, 154b, 154c, and 154d are disposed on and electrically connected to the gate structures 111, 112, 113, and 114, respectively. The front-side conductive layer 162 covers the gate structures 111 to 114 as well as the contacts 121 to 125a.

Referring to FIG. 2C, the gate structure 111 is spaced apart from the backside interconnection structure 130. The front-side conductive layers 161 to 167 are disposed over the gate structure 111. The front-side conductive layer 162 is electrically connected to the gate structure 111 by the via 154a. The front-side conductive layer 166 is electrically connected to the gate structure 111 by the via 154e.

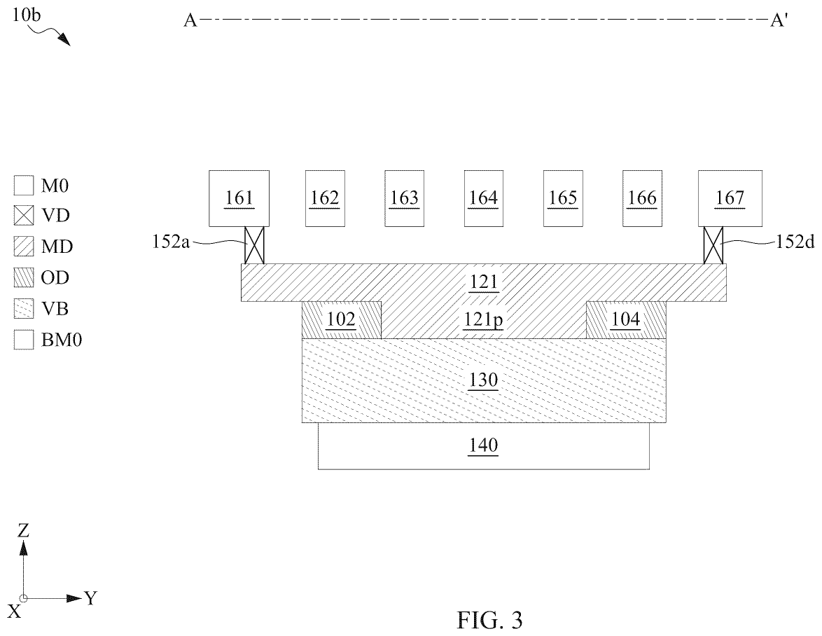

FIG. 3 is a cross-sectional view of a semiconductor device 10b in accordance with some embodiments. The semiconductor device 10b has a structure similar to that of the semiconductor device 10a. One of the differences between the semiconductor devices 10b and 10a is that the contact 121 includes a protruding portion 121p protruding toward the backside interconnection structure 130. In some embodiments, the protruding portion 121p is disposed between the active-region structures 102 and 104. In some embodiments, the protruding portion 121p is in direct contact with the backside interconnection structure 130 and builds an interface therebetween. In some embodiments, the protruding portion 121p overlaps the backside conductive layer 140 along the Z direction. In some embodiments, the protruding portion 121p is configured to add a linkage between the backside interconnection structure 130 and the contact 121, which results in a decrease in electrical resistance.

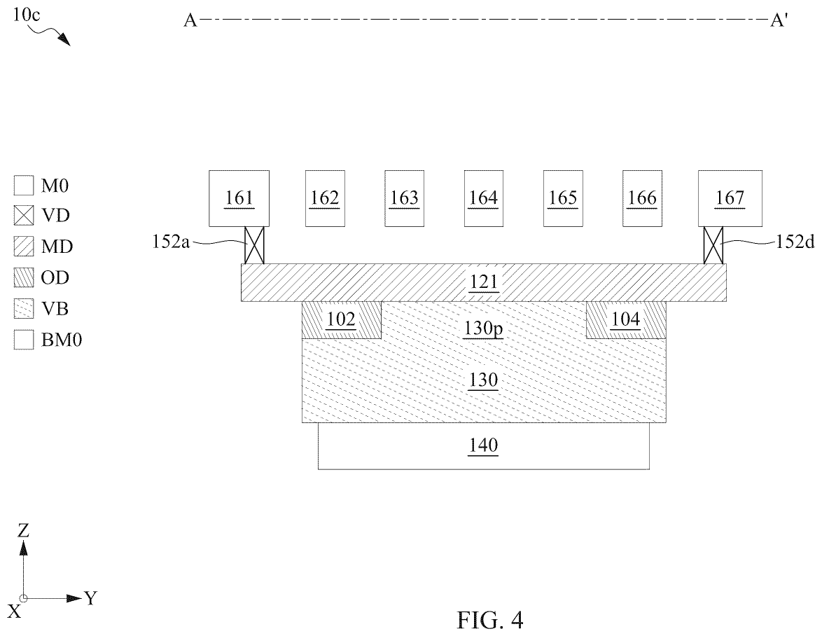

FIG. 4 is a cross-sectional view of a semiconductor device 10c in accordance with some embodiments. The semiconductor device 10c has a structure similar to that of the semiconductor device 10a. One of the differences between the semiconductor devices 10c and 10a is that the backside interconnection structure 130 includes a protruding portion 130p protruding toward the contact 121. In some embodiments, the protruding portion 130p is disposed between the active-region structures 102 and 104. In some embodiments, the protruding portion 130p is in direct contact with the contact 121 and builds an interface therebetween. In some embodiments, the protruding portion 130p overlaps the backside conductive layer 140 along the Z direction. In some embodiments, the protruding portion 130p is configured to add a linkage between the backside interconnection structure 130 and the contact 121, which results in a decrease in electrical resistance. Although FIGS. 3 to FIG. 4 illustrate that the backside interconnection structure 130 and/or the contact 121 may have a protruding portion(s), it should be noted that the protruding portion(s) can be formed by an additional step which is different from a step for producing the backside interconnection structure 130 and/or the contact 121.

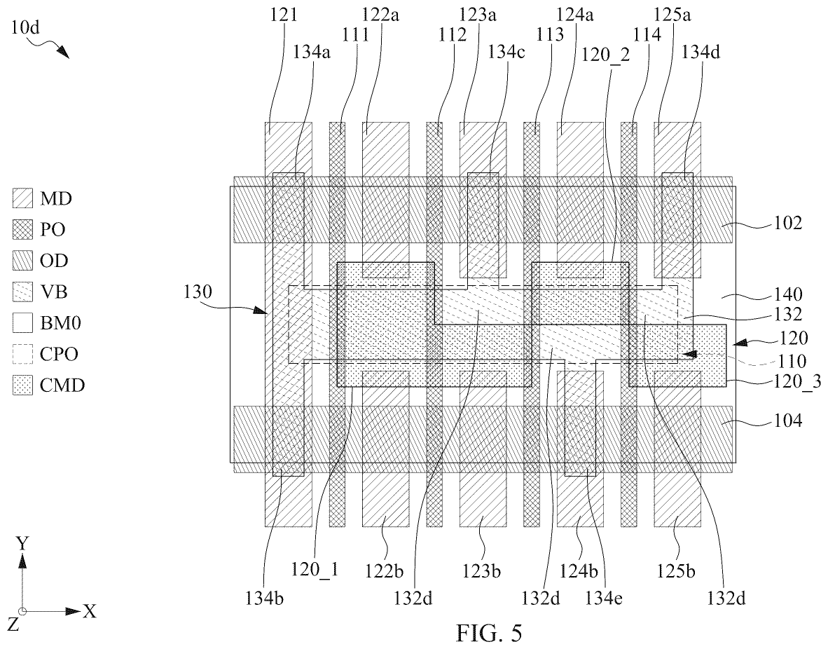

FIG. 5 is a layout diagram of a semiconductor device 10d in accordance with some embodiments. The semiconductor device 10d has a structure similar to that of the semiconductor device 10a. One of the differences between the semiconductor devices 10d and 10a is that the semiconductor devices 10d includes a cut-poly pattern 110 and a cut-MD pattern 120.

In some embodiments, the cut-poly pattern 110 is configured to disconnect the gate structures 111 to 114 to avoid leakage. The cut-poly pattern 110 may define a gap of the gate structure 111 (or 112 to 114). Dielectric material(s) may fill the cut-poly pattern 110. In some embodiments, the cut-poly pattern 110 is disposed between the active-region structures 102 and 104 in a top view. In some embodiments, the cut-poly pattern 110 overlaps the main portion 132 of the backside interconnection structure 130 along the Z direction. In some embodiments, the cut-poly pattern 110 can be referred to as a poly cut layer “CPO.”

In FIG. 5, the cut-MD pattern 120 includes portions 120_1, 120_2 and 120_3. The portion 120_1 overlaps the contact 122a, 122b, and 123b along the Z direction. The portion 120_2 overlaps the contact 124a along the Z direction. The portion 120_3 overlaps the contact 125b along the Z direction. In some embodiments, the cut-MD pattern 120 is configured to disconnect the contacts 121, 122a to 125a, and/or 122b to 125b to avoid leakage between the MDs. For example, the portion 120_1 of the cut-MD pattern 120 can avoid leakage between the contacts 122a and 123a. Dielectric material(s) may fill the cut-MD pattern 120. In some embodiments, the cut-MD pattern 120 is disposed between the active-region structures 102 and 104. In some embodiments, the cut-MD pattern 120, including portions 120_1, 120_2 and 120_3, overlaps a portion of the main portion 132 of the backside interconnection structure 130 along the Z direction. In some embodiments, a portion of the main portion 132 is free from overlapping the cut-MD pattern 120 along the Z direction. In some embodiments, the profile of the cut-MD pattern 120 depends on the location of the fingers (e.g., the fingers 134c, 134d, and 134e) of the backside interconnection structure 130. For example, the backside interconnection structure 130 includes segments 132d connected to the fingers (e.g., the fingers 134c, 134d, and 134e). The segment 132d is free from overlapping the cut-MD pattern 120 along the Z direction, and the segment 132d overlaps the cut-poly pattern 110 along the Z direction. In some embodiments, the cut-MD pattern 120 can be referred to as an MD cut layer “CMD” or a source/drain contact cut layer.

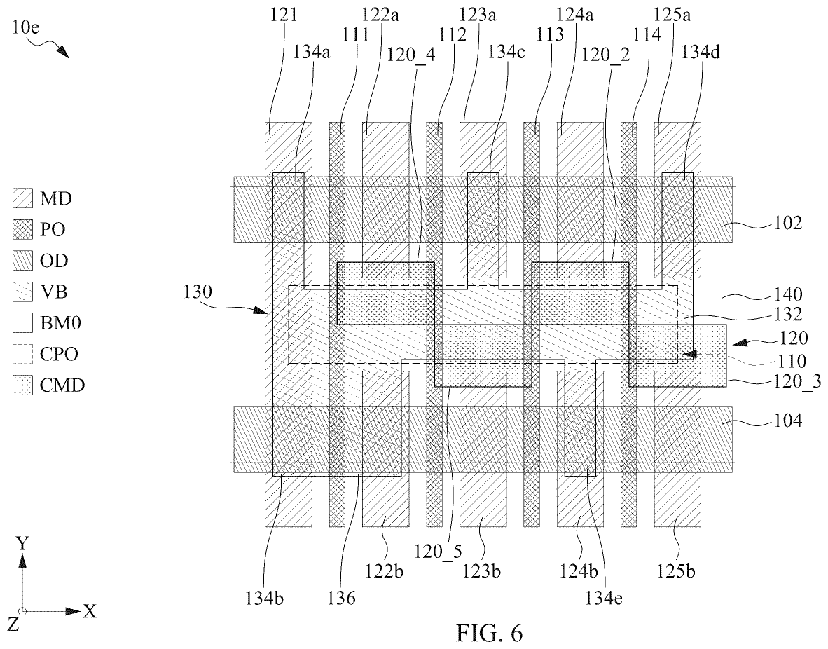

FIG. 6 is a layout diagram of a semiconductor device 10e in accordance with some embodiments. The semiconductor device 10e has a structure similar to that of the semiconductor device 10d. One of the differences between the semiconductor devices 10e and 10d is that the backside interconnection structure 130 of the semiconductor devices 10e includes an extension 136. In FIG. 6, the cut-MD pattern 120 includes portions 120_2, 120_3, 120_4 and 120_5. The portion 120_4 overlaps the contact 122a along the Z direction. The portion 120_5 overlaps the contact 123b along the Z direction.

In some embodiments, the extension 136 is connected to the main portion 132. The extension 136 is connected to the finger 134d. In some embodiments, the extension 136 is free from overlapping the cut-poly pattern 110. In some embodiments, the extension 136 is free from overlapping the cut-MD pattern 120. In some embodiments, the extension 136 extends from the contact 121 to the contact 122b through the gate structure 111 in a top view. In some embodiments, the extension 136 overlaps the gate structure 111 and the active-region structure 104 along the Z direction. In some embodiments, the extension 136 overlaps a region between the contacts 121 and 122b along the Z direction. In some embodiments, the extension 136 is disposed on a dummy region where no signal passes through, which thereby enhances the overlapping area between the backside interconnection structure 130 and the backside conductive layer 140.

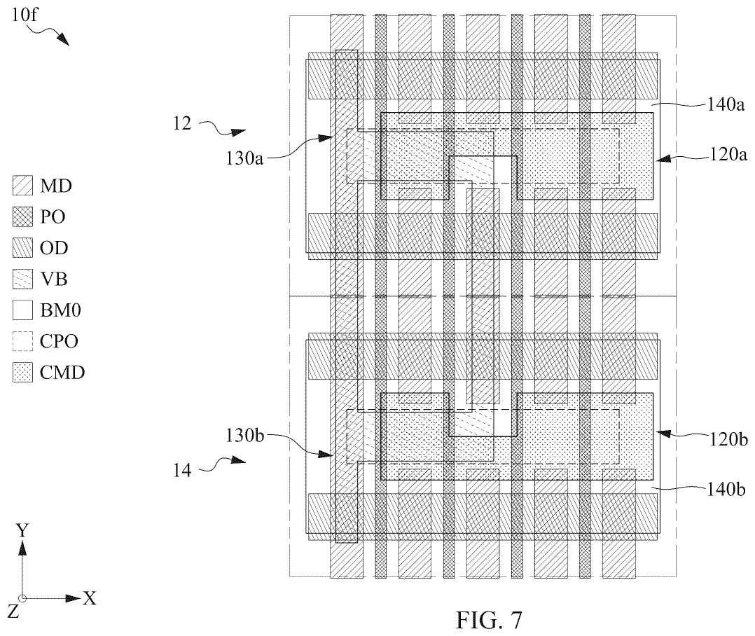

FIG. 7 is a layout diagram of a semiconductor device 10f in accordance with some embodiments. In some embodiments, the semiconductor device 10f includes a cell 12 and a cell 14 abutting the cell 12. Each of the cells 12 and 14 has features (e.g., the gate structure, source/drain contact, backside interconnection structure, backside conductive layer, and/or other features) that are the same as or similar to those of the semiconductor device 10a as shown in FIG. 1A.

The cell 12 includes a backside interconnection structure 130a and a backside conductive layer 140a configured to transmit a power signal. The backside interconnection structure 130a is electrically connected to the backside conductive layer 140a. The cell 12 includes a cut-MD pattern 120a configured to disconnect the source/drain contacts within the cell 12. The cell 14 has a backside interconnection structure 130b and a backside conductive layer 140b configured to transmit a power signal. The backside interconnection structure 130b is electrically connected to the backside conductive layer 140b. The cell 14 includes a cut-MD pattern 120b configured to disconnect the source/drain contacts within the cell 14. In some embodiments, each of the backside interconnection structures 130a and 130b has a main portion extending along the X direction and multiple fingers connected to the main portion and extending along the Y direction. In some cases, when the backside conductive layers 140a and 140b are configured to transmit the same power signal, the backside interconnection structure 130a can be connected to the backside interconnection structure 130b, which results in a reduction in the resistance for transmitting power. In this embodiment, the backside interconnection structures 130a and 130b define an O-shaped profile. In other embodiments, the backside interconnection structures 130a and 130b can define other profiles depending on the location of fingers.

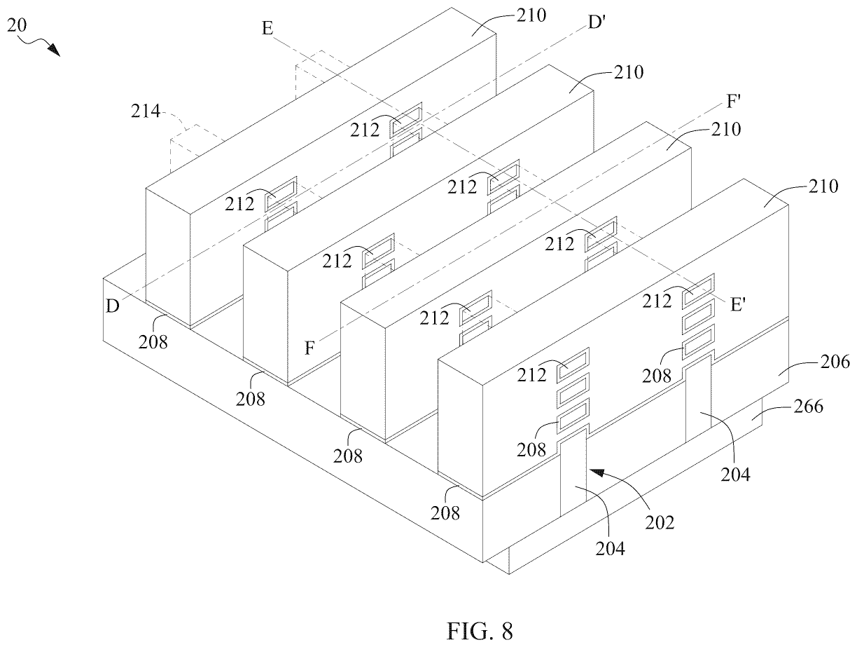

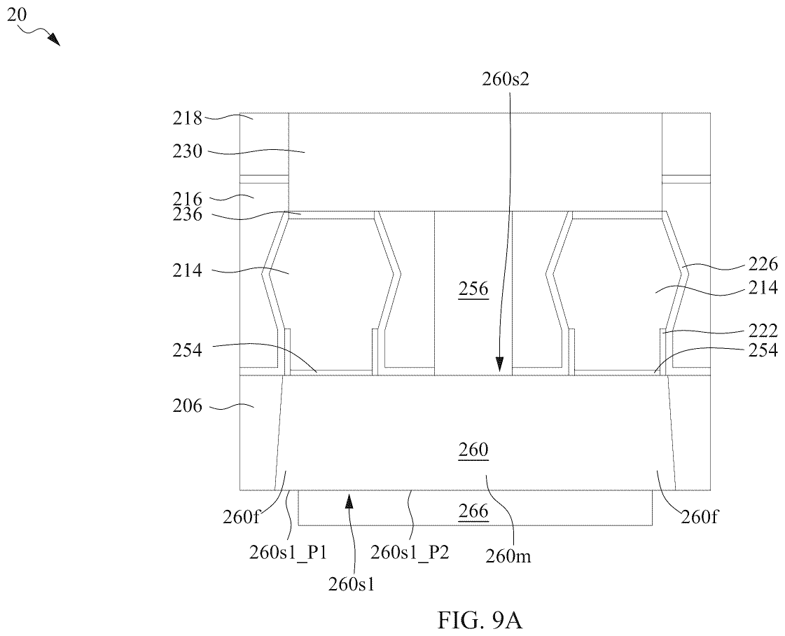

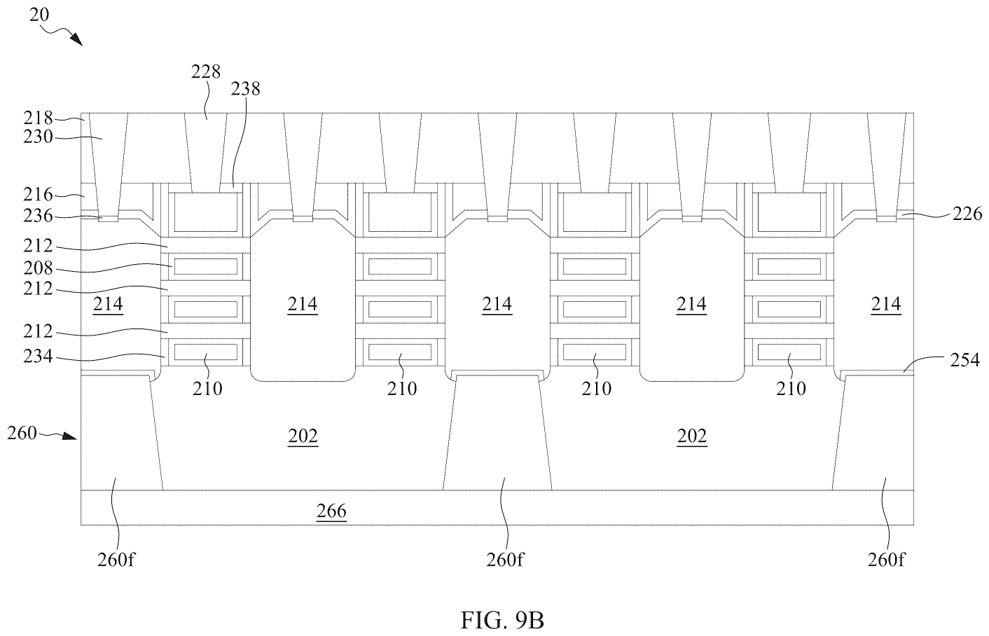

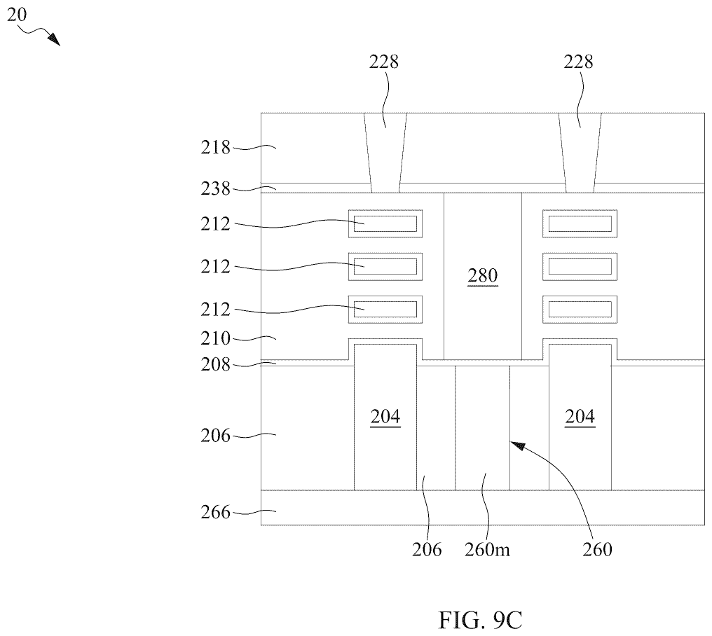

In some embodiments, the layout diagram of the semiconductor devices 10a to 10f can be applied to a semiconductor device including nano-sheet transistors. FIG. 8 and FIGS. 9A to FIG. 9C illustrate a semiconductor device 20 which has a layout diagram the same as or similar to that as shown in FIG. 1A. It should be noted that some features are omitted from FIG. 8 for brevity, and the detailed structure is shown in FIGS. 9A to FIG. 9C.

Referring to FIG. 8, in some embodiments, the semiconductor device 20 includes a substrate 202 which includes a plurality of fins 204 protruding upwardly. In some embodiments, the semiconductor device 20 further includes a plurality of isolation regions 206 surrounding the fins 204. In some embodiments, the backside of the substrate 202 is ground or polished until the isolation regions 206 are exposed, and a backside conductive layer 266 is formed on a backside of the substrate 202 to cover the isolation regions 206 and the substrate 202.

A plurality of nanostructures 212 are disposed over the substrate 202 and the fins 204. A plurality of gate dielectric layers 208 are disposed over the substrate 202 and the fins 204 and surround the nanostructures 212. A plurality of gate electrodes 210 are disposed over the gate dielectric layers 208. A plurality of epitaxial structures 214 (shown by dotted lines) are disposed over the substrate 202 and connected to the nanostructures 212.

FIG. 9A, FIG. 9B, and FIG. 9C are cross-sectional views taken along lines D-D′, E-E′ and F-F′ of the semiconductor device 20, respectively. As shown in FIGS. 9A-9C, the semiconductor device 20 further includes a dielectric layer 216 that is disposed over the isolation regions 206 and a dielectric layer 218 that is disposed over the dielectric layer 216. The epitaxial structures 214 and the gate electrodes 210 are disposed in the dielectric layer 216. In some embodiments, the semiconductor device 20 further includes a plurality of spacers 234 (see FIG. 9B) that are connected to side walls of the gate dielectric layers 208 around the gate electrodes 210. In some embodiments, the semiconductor device 20 further includes a plurality of spacers 222 that are disposed in the dielectric layer 216 and that surround lower portions of the epitaxial structures 214. In some embodiments, the semiconductor device 20 further includes a contact etch stop layer 226 that is disposed in the dielectric layer 216 and around the epitaxial structures 214. In some embodiments, the semiconductor device 20 further includes a plurality of gate masks 238 that are disposed in the dielectric layer 216, and over the gate electrodes 210. In some embodiments, the semiconductor device 20 further includes a plurality of gate contacts 228 that are disposed in the dielectric layer 218, and that are connected to the gate electrodes 210. In some embodiments, the semiconductor device 20 further includes a plurality of source/drain contacts 230 that are disposed in the dielectric layers 216 and 218. The source/drain contacts 230 are connected to the epitaxial structures 214. In some embodiments, the semiconductor device 20 further includes a plurality of silicide structures 236 that are connected between the epitaxial structures 214 and the source/drain contacts 230.

In some embodiments, the substrate 202 may be a suitable substrate, such as an elemental semiconductor or a compound semiconductor. The elemental semiconductor may contain a single species of atom, such as Si Ge or other suitable materials. The compound semiconductor may be composed of at least two elements, such as GaAs, SiC, SiGe, GaP, InSb, InAs, InP, GaAsP, GainAs, AlGaAs, AlInAs, GaInAsP, or the like. In some embodiments, the composition of the compound semiconductor including the aforesaid elements may vary by having one ratio at one location and another ratio at a different location (i.e., the compound semiconductor may have a gradient composition). In some embodiments, the substrate 202 may be a semiconductor-on-insulator (SOI) substrate, such as silicon germanium-on-insulator (SGOI) substrate, or the like. In some embodiments, an SOI substrate may include an epitaxially grown semiconductor layer, such as Si, Ge, SiGe, any combination thereof, or the like, which is formed over an oxide layer.

In some embodiments, the isolation regions 206 may include or be made of an insulating material, such as silicon oxide, or other suitable materials, and may be made by chemical vapor deposition (CVD), or other suitable techniques. The isolation region 206 includes STI or other suitable structures.

In some embodiments, the gate dielectric layers 208 may include or be made of a high-k dielectric material, such as a metal oxide or silicate of hafnium, aluminum, zirconium, lanthanum, manganese, barium, titanium, lead, other suitable materials, or any combination thereof, and may be made by CVD, atomic layer deposition (ALD), other suitable techniques, or any combination thereof.

In some embodiments, the gate electrodes 210 may include or be made of titanium nitride, titanium oxide, tantalum nitride, tantalum carbide, cobalt, ruthenium, aluminum, tungsten, other suitable materials, or any combination thereof, and may be made by physical vapor deposition (PVD), other suitable techniques, or any combination thereof.

In some embodiments, each of the nanostructures 212 may include or be made of silicon, silicon germanium, silicon carbide, other suitable materials, or any combination thereof, and may be made by CVD, ALD, other suitable techniques, or any combination thereof.

In some embodiments, each of the epitaxial structures 214 may include or be made of silicon, silicon carbide, silicon phosphide, other suitable materials, or any, combination thereof, and may be made by CVD, ALD, vapor phase epitaxy (VPE), molecular beam epitaxy (MBE), other suitable techniques, or any combination thereof.

In some embodiments, each of the dielectric layers 216 and 218 may include or be made of SiOx, SiOxCy, SiOxCyHz, SiCx, SiNx, other suitable materials, or any combination thereof, and may be made by CVD, other suitable techniques, or any combination thereof.

In some embodiments, the spacers 222 and 234 may include or be made of silicon oxide, silicon nitride, silicon oxynitride, other suitable materials, or any combination thereof, and may be made by CVD, ALD, other suitable techniques, or any combination thereof.

In some embodiments, the contact etch stop layer 226 may include or be made of silicon nitride, silicon oxide, silicon oxynitride, other suitable materials, or any combination thereof, and may be made by CVD, ALD, other suitable techniques, or any combination thereof.

In some embodiments, each of the gate contacts 228 and the source/drain contacts 230 may include or be made of Cu, Ni, Ti, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof.

In some embodiments, the silicide structures 236 may include or be made of NiSi, TiSi, TiNiSi, TiSiGe, NiSiGe, TiNiSiGe, RuSi, CoSi, MoSi, PtSi, TaSi, WSi, CrSi, ZrSi, other suitable materials, or any combination thereof.

In some embodiments, the gate masks 238 may include or be made of silicon oxide, silicon nitride, silicon oxynitride, other suitable materials, or any combination thereof, and may be made by CVD, PVD, other suitable techniques, or any combination thereof.

In some embodiments, the semiconductor device 20 further includes a backside interconnection structure 260. In some embodiments, a portion of the isolation regions 206 and a portion of the fins 204 are removed to form a trench. The backside interconnection structure 260 is formed within the trench.

In some embodiments, the backside interconnection structure 260 is disposed under the epitaxial structures 214. A plurality of silicide structures 254 are connected between the epitaxial structures 214 and the backside interconnection structure 260. In some embodiments, the backside interconnection structure 260 continuously extends from one epitaxial structure 214 to another epitaxial structure 214 as shown in FIG. 9A. The backside interconnection structure 260 may include or be made of Cu, Ni, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. The backside interconnection structure 260 may be referred to as a backside via (VB). In some embodiments, the backside interconnection structure 260 includes a main portion 260m and fingers 260f. The finger 260f is connected to the bottom of the epitaxial structure 214. The main portion 260m is connected to multiple fingers 260f. In some embodiments, the main portion 260m is disposed between two abutting fins 204.

In some embodiments, the semiconductor device 20 further includes a backside conductive layer 266. The backside conductive layer 266 is disposed under the backside interconnection structure 260. The backside conductive layer 266 may function as a power rail for providing electric power to the epitaxial structures 214. The backside conductive layer 266 may include or be made of Cu, Ni, Ti, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. The backside conductive layer 266 may be referred to as a first backside metal (BM0). The backside interconnection structure 260 has a surface 260s1 facing the backside conductive layer 266 and a surface 260s2 opposite to the surface 260s1 (see FIG. 9A). The surface 260s1 has parts 260s1_P1 and 260s1_P2. The part 260s1_P1 is exposed by the backside conductive layer 266 along a direction from the surface 260s1 toward the surface 260s2. The part 260s1_P2 is covered by the backside conductive layer 266 along a direction from the surface 260s1 toward the surface 260s2.

In some embodiments, the semiconductor device 20 further includes a conductive structure 256 (see FIG. 9A). The conductive structure 256 is formed within the dielectric layer 216. The conductive structure 256 is disposed between two abutting epitaxial structures 214. In some embodiments, the conductive structure 256 electrically connects the backside interconnection structure 260 and the source/drain contact 230, which thereby results in a reduction in the resistance for transmitting power. In some embodiments, the conductive structure 256 may include or be made of Cu, Ni, Ti, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. In some embodiments, the conductive structure 256 can be a protruding portion of the backside interconnection structure 260. In some embodiments, the conductive structure 256 can be a protruding portion of the source/drain contact 230. In some embodiments, the conductive structure 256 can include two parts which are the protruding portion of the backside interconnection structure 260 and the protruding portion of the source/drain contact 230.

In some embodiments, the semiconductor device 20 further includes a cutting feature 280 (see FIG. 9C) within the gate electrode 210. In some embodiments, the cutting feature 280 is disposed over the main portion 260m of the backside interconnection structure 260. In some embodiments, the cutting feature 280 is configured to disconnect the gate electrode 210 to avoid leakage between the gate electrode 210 and the backside interconnection structure 260 in a condition in which the formation of the opening for accommodating the backside interconnection structure 260 is overetched. In some embodiments, the cutting feature 280 may include or be made of silicon oxide, silicon nitride, silicon oxynitride, other suitable materials, or any combination thereof, and may be made by CVD, PVD, other suitable techniques, or any combination thereof. The cutting feature 280 can also be referred to as “CPO.”

In this embodiment, the semiconductor device 20 includes the backside interconnection structure 260 with the main portion 260m. The main portion 260m is configured to enhance the overlapping area between the backside interconnection structure 260 and the backside conductive layer 266, which results in a decrease in electrical resistance.

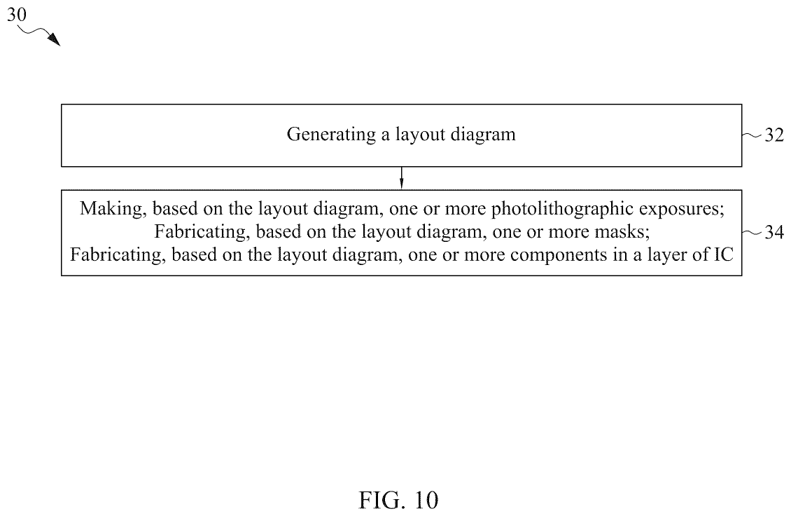

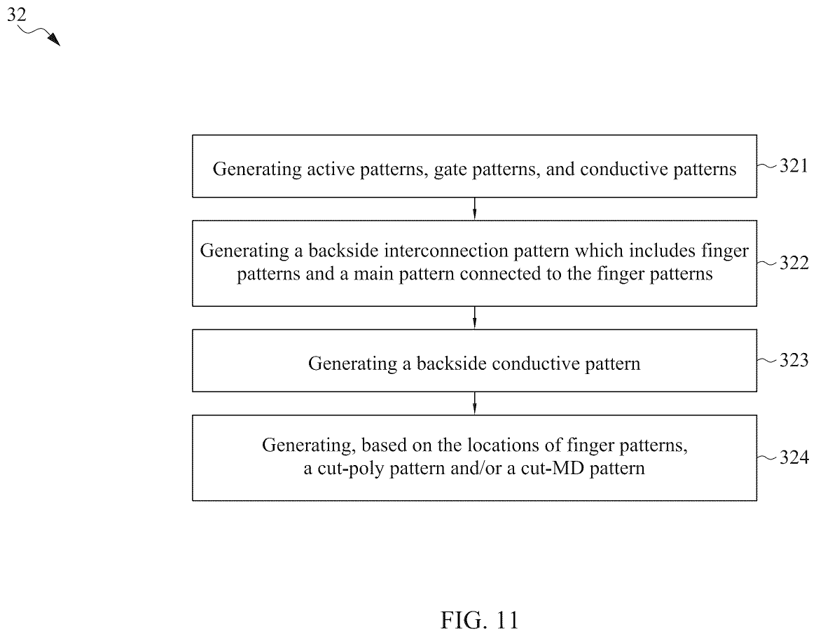

FIG. 10 and FIG. 11 are flowcharts of a method for manufacturing a layout of a semiconductor device according to various aspects of the present disclosure. FIG. 10 illustrates a method 30 of manufacturing a semiconductor device in accordance with some embodiments. The generation of the layout diagram is discussed in more detail as follows with respect to FIG. 11.

In some embodiments, the method 30 includes operations 32 and 34. The method begins with the operation 32, in which a layout diagram is generated.

The method 30 continues with the operation 34: based on the layout diagram, in which at least one of (A) one or more photolithographic exposures are made or (B) one or more semiconductor masks are fabricated or (C) one or more components in a layer of a semiconductor device are fabricated.

As shown in FIG. 11, the operation 32 includes operations 321, 322, 323, and 324. In some embodiments, the operation 321 includes generating active patterns, gate patterns, and conductive patterns. In some embodiments, the active patterns correspond to the active-region structures 102 and 104 as shown in FIG. 1A. In some embodiments, the gate patterns correspond to the gate structures 111 to 114 as shown in FIG. 1A. In some embodiments, the conductive patterns correspond to the contacts 121, 122a to 125a, and 122b to 125b as shown in FIG. 1A.

In some embodiments, the operation 322 includes generating a backside interconnection pattern which includes finger patterns and a main pattern connected to the finger patterns. In some embodiments, the backside interconnection pattern corresponds to the backside interconnection structure 130 as shown in FIG. 1A. In some embodiments, the finger patterns correspond to the fingers 134a to 134e as shown in FIG. 1A. In some embodiments, the main pattern corresponds to the main portion 132 as shown in FIG. 1A.

In some embodiments, the operation 323 includes generating a backside conductive pattern. In some embodiments, the backside conductive pattern corresponds to the backside conductive layer 140 as shown in FIG. 1A.

In some embodiments, the operation 324 includes, based on the locations of finger patterns, generating a cut-poly pattern and/or a cut-MD pattern. In some embodiments, the cut-poly pattern corresponds to the cut-poly pattern 110 as shown in FIG. 5. In some embodiments, the cut-MD pattern corresponds to the cut-MD pattern 120 as shown in FIG. 5.

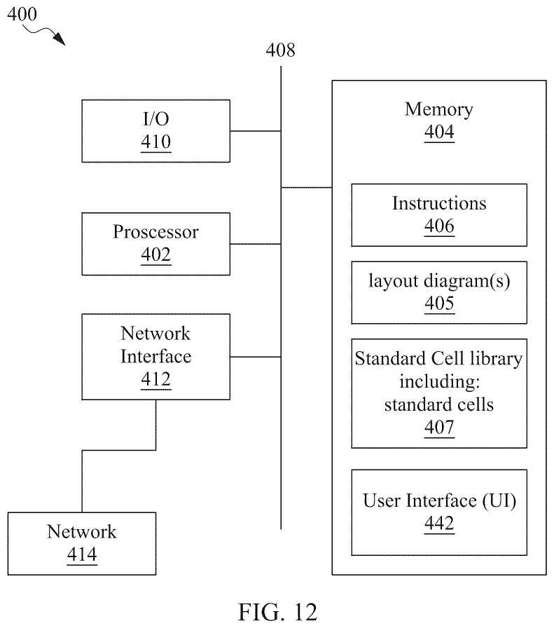

FIG. 12 is a block diagram of a system 400 of designing a semiconductor device, in accordance with some embodiments. The system 400 can include, for example, an electronic design automation (EDA) system.

In some embodiments, system 400 includes an automatic placement and routing (APR) system. Methods described herein of generating PG layout diagrams, in accordance with one or more embodiments, are implementable, for example, using the system 400, in accordance with some embodiments.

In some embodiments, system 400 is a general purpose computing device including a hardware processor 402 and a non-transitory, computer-readable storage medium 404. Storage medium 404, amongst other things, is encoded with, i.e., stores, computer program code 406, i.e., a set of executable instructions. Execution of instructions 406 by hardware processor 402 represents (at least in part) an EDA tool which implements a portion or all of a method according to an embodiment, e.g., the methods described herein in accordance with one or more embodiments. (hereinafter, the noted processes and/or methods).

Processor 402 is electrically coupled to computer-readable storage medium 404 via a bus 408. Processor 402 is also electrically coupled to an I/O interface 410 by bus 408. A network interface 412 is also electrically connected to processor 402 via bus 408. Network interface 412 is connected to a network 414, so that processor 402 and computer-readable storage medium 404 are capable of connecting to external elements via network 414. Processor 402 is configured to execute computer program code 406 encoded in computer-readable storage medium 404 in order to cause system 400 to be usable for performing a portion or all of the noted processes and/or methods. In one or more embodiments, processor 402 is a central processing unit (CPU), a multi-processor, a distributed processing system, an application specific integrated circuit (ASIC), and/or a suitable processing unit.

In one or more embodiments, computer-readable storage medium 404 is an electronic, magnetic, optical, electromagnetic, infrared, and/or semiconductor system (or apparatus or device). For example, computer-readable storage medium 404 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 404 includes a compact disk-read only memory (CD-ROM), a compact disk-read/write (CD-R/W), and/or a digital video disc (DVD).

In one or more embodiments, storage medium 404 stores computer program code (instructions) 406 configured to cause system 400 (where such execution represents (at least in part) the EDA tool) to be usable for performing a portion or all of the noted processes and/or methods. In one or more embodiments, storage medium 404 also stores information which facilitates performing a portion or all of the noted processes and/or methods. In one or more embodiments, storage medium 404 stores library 407 of standard cells including such standard cells as disclosed herein and one or more layout diagrams 405 such as are disclosed hercin.

System 400 includes I/O interface 410. I/O interface 410 is coupled to external circuitry. In one or more embodiments, I/O interface 410 includes a keyboard, keypad, mouse, trackball, trackpad, touchscreen, and/or cursor direction keys for communicating information and commands to processor 402.

System 400 also includes network interface 412 coupled to processor 402. Network interface 412 allows system 400 to communicate with network 414, to which one or more other computer systems are connected. Network interface 412 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 400.

System 400 is configured to receive information through I/O interface 410. The information received through I/O interface 410 includes one or more of instructions, data, design rules, libraries of standard cells, and/or other parameters for processing by processor 402. The information is transferred to processor 402 via bus 408. System 400 is configured to receive information related to a UI through I/O interface 410. The information is stored in computer-readable medium 404 as user interface (UI) 442.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods are implemented as a software application running on System 400. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

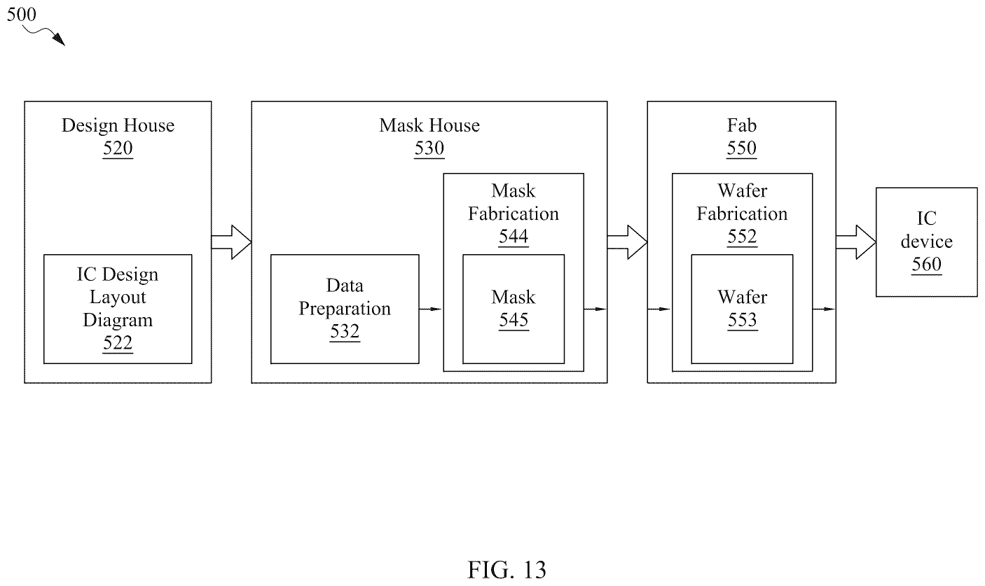

FIG. 13 is a block diagram of a semiconductor device manufacturing system 500, and a semiconductor device flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 500.

In FIG. 13, IC manufacturing system 500 includes entities, such as a design house 520, a mask house 530, and an IC manufacturer/fabricator (“fab”) 550, that interact with one another in the design, development, and manufacturing cycles and/or services related to manufacturing an IC device 560. The entities in system 500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 520, mask house 530, and IC fab 550 is owned by a single larger company. In some embodiments, two or more of design house 520, mask house 530, and IC fab 550 coexist in a common facility and use common resources.

Design house (or design team) 520 generates an IC design layout diagram 522. IC design layout diagram 522 includes various geometrical patterns designed for an IC device 560. The geometrical patterns correspond to patterns of metal, oxide, or semiconductor layers that make up the various components of IC device 560 to be fabricated. The various layers combine to form various IC features. For example, a portion of IC design layout diagram 522 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 520 implements a proper design procedure to form IC design layout diagram 522. The design procedure includes one or more of logic design, physical design or place and route. IC design layout diagram 522 is presented in one or more data files having information of the geometrical patterns. For example, IC design layout diagram 522 can be expressed in a GDSII file format or DFII file format.

Mask house 530 includes data preparation 532 and mask fabrication 544. Mask house 530 uses IC design layout diagram 522 to manufacture one or more masks 545 to be used for fabricating the various layers of IC device 560 according to IC design layout diagram 522. Mask house 530 performs mask data preparation 532, where IC design layout diagram 522 is translated into a representative data file (“RDF”). Mask data preparation 532 provides the RDF to mask fabrication 544. Mask fabrication 544 includes a mask writer. A mask writer converts the RDF to an image on a substrate, such as a mask (reticle) 545 or a semiconductor wafer 553. The design layout diagram 522 is manipulated by mask data preparation 532 to comply with particular characteristics of the mask writer and/or requirements of IC fab 550. In FIG. 13, mask data preparation 532 and mask fabrication 544 are illustrated as separate elements. In some embodiments, mask data preparation 532 and mask fabrication 544 can be collectively referred to as mask data preparation.

In some embodiments, mask data preparation 532 includes optical proximity correction (OPC) which uses lithography enhancement techniques to compensate for image errors, such as those that can arise from diffraction, interference, other process effects and the like. OPC adjusts IC design layout diagram 522. In some embodiments, mask data preparation 532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 532 includes a mask rule checker (MRC) that checks the IC design layout diagram 522 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 522 to compensate for limitations during mask fabrication 544, which may undo part of the modifications performed by OPC in order to meet mask creation rules.

In some embodiments, mask data preparation 532 includes lithography process checking (LPC) that simulates processing that will be implemented by IC fab 550 to fabricate IC device 560. LPC simulates this processing based on IC design layout diagram 522 to create a simulated manufactured device, such as IC device 560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 522.

It should be understood that the foregoing description of mask data preparation 532 has been simplified for the purposes of clarity. In some embodiments, data preparation 532 includes additional features such as a logic operation (LOP) to modify the IC design layout diagram 522 according to manufacturing rules. Additionally, the processes applied to IC design layout diagram 522 during data preparation 532 may be executed in a variety of different orders.

After mask data preparation 532 and during mask fabrication 544, a mask 545 or a group of masks 545 are fabricated based on the modified IC design layout diagram 522. In some embodiments, mask fabrication 544 includes performing one or more lithographic exposures based on IC design layout diagram 522. In some embodiments, an electron-beam (e-beam) or a mechanism of multiple e-beams is used to form a pattern on a mask (photomask or reticle) 545 based on the modified IC design layout diagram 522. Mask 545 can be formed in various technologies. In some embodiments, mask 545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 545 includes a transparent substrate (e.g., fused quartz) and an opaque material (e.g., chromium) coated in the opaque regions of the binary mask. In another example, mask 545 is formed using a phase shift technology. In a phase shift mask (PSM) version of mask 545, various features in the pattern formed on the phase shift mask are configured to have proper phase difference to enhance the resolution and imaging quality. In various examples, the phase shift mask can be attenuated PSM or alternating PSM. The masks generated by mask fabrication 544 are used in a variety of processes. For example, such a mask(s) can be used in an ion implantation process to form various doped regions in semiconductor wafer 553, in an etching process to form various etching regions in semiconductor wafer 553, and/or in other suitable processes.

IC fab 550 includes wafer fabrication 552. IC fab 550 is an IC fabricator that includes one or more manufacturing facilities for the fabrication of a variety of different IC products. In some embodiments, IC Fab 550 can be a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 550 uses mask(s) 545 fabricated by mask house 530 to fabricate IC device 560. Thus, IC fab 550 at least indirectly uses IC design layout diagram 522 to fabricate IC device 560. In some embodiments, semiconductor wafer 553 is fabricated by IC fab 550 using mask(s) 545 to form IC device 560. In some embodiments, the IC fabrication includes performing one or more lithographic exposures based at least indirectly on IC design layout diagram 522. Semiconductor wafer 553 includes a silicon substrate or other proper substrate having material layers formed thereon. Semiconductor wafer 553 further includes one or more of various doped regions, dielectric features, multilevel interconnects, and the like (formed at subsequent manufacturing steps).

Details regarding an integrated circuit (IC) manufacturing system (e.g., system 500 of FIG. 13), and an IC manufacturing flow associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, the entireties of each of which are hereby incorporated by reference.

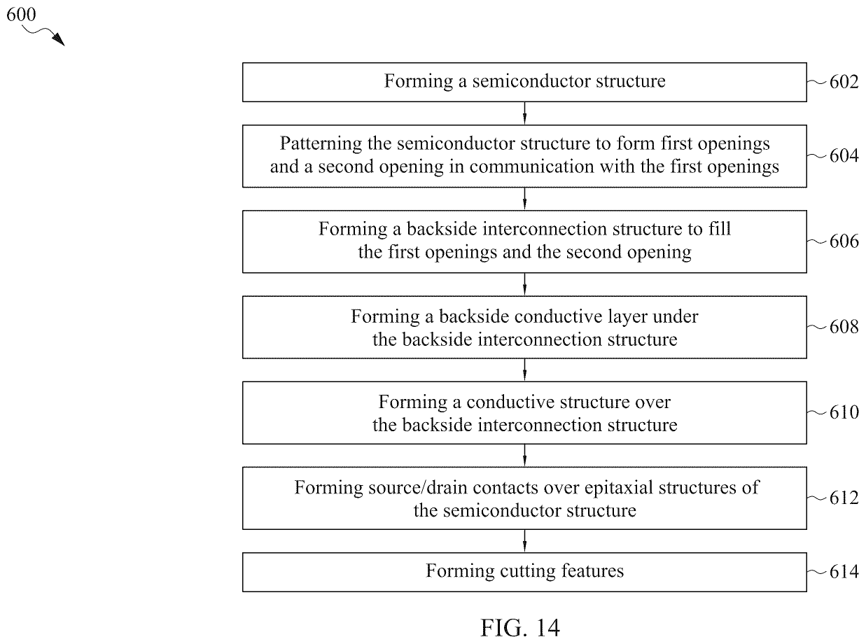

FIG. 14 is a flowchart of a method 600 for manufacturing a semiconductor device (e.g., the semiconductor devices 10a-10f and 20), in accordance with some embodiments.

The method 600 begins with operation 602 in which a semiconductor structure is formed. In some embodiments, the semiconductor structure includes a substrate (e.g., the substrate 202) and fins (e.g., the fins 204) over the substrate. The fins define a plurality of trenches over the substrate. In some embodiments, the semiconductor structure includes isolation regions (e.g., the isolation regions 206) filling the trenches and surrounded by the fins. In some embodiments, the semiconductor structure includes gate structures extending along a first direction. Each of the gate structures includes nanostructures (e.g., the nanostructures 212), a gate dielectric layer (e.g., the gate dielectric layer 208), and a gate electrode (e.g., the gate electrode 210). In some embodiments, the semiconductor structure includes epitaxial structures (e.g., epitaxial structures 214) over the fins. In some embodiments, the semiconductor structure includes an interlayer dielectric (ILD, e.g., the dielectric layer 216) covering the epitaxial structures.

The method 600 continues with operation 604 in which the semiconductor structure is patterned. In some embodiments, portions of the fins under the epitaxial structures are removed to form first openings (the opening for accommodating the fingers 260f of a backside via) exposing the epitaxial structure. In some embodiments, portions of the isolation regions are removed to form a second opening (the opening for accommodating the main portion 260m of a backside via). In some embodiments, the second openings correspondingly are in communication with the first openings.

The method 600 continues with operation 606 in which a backside interconnection structure (e.g., the backside interconnection structure 260) is formed to fill the first openings and the second openings. The backside interconnection structure includes a main portion (e.g., the main portion 260m) and fingers (e.g., the finger 260f) connected by the main portion.

The method 600 continues with operation 608 in which a backside conductive layer (e.g., the backside conductive layer 266) is formed under the backside interconnection structure.

The method 600 continues with operation 610 in which a conductive structure (e.g., the conductive structure 256) is formed over the main portion of the backside interconnection structure. In some embodiments, a portion of the ILD is removed to form a third opening (e.g., the opening for accommodating the conductive structure 256) exposing the backside interconnection structure. In some embodiments, the conductive structure is formed within the third opening.

The method 600 continues with operation 612 in which source/drain contacts (e.g., the source/drain contacts 230) are formed over the epitaxial structures of the semiconductor structure. Each of the source/drain contacts extends along the first direction. In some embodiments, the source/drain contact is electrically connected to the backside interconnection structure through the conductive structure.

The method 600 continues with operation 614 in which cutting structures are formed. In some embodiments, the cutting structures include CPO (e.g., the cutting feature 280) configured to cut a portion of the gate structures. In some embodiments, the cutting structures include CMD (e.g., the cut-MD pattern 120) configured to cut a portion of the source/drain contacts.

The method 600 is merely an example, and is not intended to limit the present disclosure beyond what is explicitly recited in the claims. Additional operations can be provided before, during, and after the method 600, and some operations described can be replaced, eliminated, or reordered for additional embodiments of the method.

Some embodiments of the present disclosure provide a semiconductor device. The semiconductor device includes a first type active region structure and a second type active region structure extending along a first direction. The semiconductor device also includes a first S/D contact over the first type active region structure and extending along a second direction different from the first direction. The semiconductor device further includes a backside conductive layer under the first type active region structure. In addition, the semiconductor device includes a backside interconnection structure between the backside conductive layer and the first type active region structure. The backside interconnection structure includes a first portion between the backside conductive layer and the first type active region structure, a second portion between the backside conductive layer and the second type active region structure, and a third portion connecting the first portion and the second portion.

Some embodiments of the present disclosure provide a semiconductor device. The semiconductor device includes a substrate. The semiconductor device also includes a first epitaxial structure and a second epitaxial structure on the substrate. The semiconductor device further includes a backside conductive layer under the substrate. In addition, the semiconductor device includes a backside interconnection structure between the backside conductive layer and the first epitaxial structure and between the backside conductive layer and the second epitaxial structure.

Some embodiments of the present disclosure provide a method of manufacturing a semiconductor device. The method includes providing a substrate and forming a first epitaxial structure and a second epitaxial structure on the substrate. The method also includes forming a backside interconnection structure under the first epitaxial structure and under the second epitaxial structure. The backside interconnection structure includes a first finger connected to the first epitaxial structure, a second finger connected to the second epitaxial structure, and a main portion connecting the first finger to the second finger. The method further includes forming a backside conductive layer under the backside interconnection structure.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first type active region structure and a second type active region structure extending along a first direction;
a first source/drain (S/D) contact over the first type active region structure and extending along a second direction different from the first direction;
a backside conductive layer under the first type active region structure; and;
a backside interconnection structure between the backside conductive layer and the first type active region structure,
the backside interconnection structure including a first portion coupled between the backside conductive layer and the first type active region structure, a second portion coupled between the backside conductive layer and the second type active region structure, and a third portion coupling the first portion and the second portion.

2. The semiconductor device of claim 1, wherein the first S/D contact is coupled to the third portion of the backside interconnection structure.

3. The semiconductor device of claim 1, wherein the backside interconnection structure further includes a fourth portion protruding toward the first S/D contact along a third direction different from the first direction and the second direction.

4. The semiconductor device of claim 1, wherein the first S/D contact includes a first portion protruding toward the backside interconnection structure along a third direction different from the first direction and the second direction.

5. The semiconductor device of claim 1, further comprising:
a second S/D contact over the first type active region structure and extending along the second direction; and
wherein the backside interconnection structure comprises a fourth portion coupled between the second S/D contact and the backside conductive layer and coupled to the third portion.

6. The semiconductor device of claim 5, further comprising:
a gate structure extending along the second direction and across a gap between the first type active region structure and the second type active region structure; and;
wherein the third portion overlaps the gap along a third direction different from the first direction and the second direction.

7. The semiconductor device of claim 1, further comprising:
a gate structure extending along the second direction and over the first type active region structure and the second type active region structure;
a gate structure cut layer disposed between the first type active region structure and the second type active region structure; and;
wherein the gate structure cut layer overlaps the third portion of the backside interconnection structure along a third direction different from the first direction and the second direction.

8. The semiconductor device of claim 1, further comprising:
a second S/D contact over the first type active region structure and extending along the second direction;
a third S/D contact over the second type active region structure and extending along the second direction; and;
an S/D contact cut layer between second S/D contact and the third S/D contact, wherein the S/D contact cut layer overlaps the backside interconnection structure along a third direction different from the first direction and the second direction.

9. The semiconductor device of claim 8, wherein the third portion of the backside interconnection structure extends along the first direction.

10. A semiconductor device, comprising:
a substrate;
a first epitaxial structure and a second epitaxial structure on the substrate;
a backside conductive layer under the substrate; and;
a backside interconnection structure between the backside conductive layer and the first epitaxial structure and between the backside conductive layer and the second epitaxial structure.

11. The semiconductor device of claim 10, further comprising:
a source/drain (S/D) contact over the first epitaxial structure and electrically connected to the backside interconnection structure.

12. The semiconductor device of claim 11, further comprising:
a conductive structure electrically connecting the S/D contact to the backside interconnection structure,
wherein the conductive structure is between the first epitaxial structure and the second epitaxial structure.

13. The semiconductor device of claim 10, wherein the backside interconnection structure has a first surface facing the backside conductive layer, and a portion of the first surface is exposed by the backside conductive layer along a direction substantially orthogonal to the first surface.

14. The semiconductor device of claim 10, further comprising:
a gate electrode over the substrate; and;
a cutting feature within the gate electrode, wherein the cutting feature vertically overlaps the backside interconnection structure.

15. The semiconductor device of claim 10, wherein the backside interconnection structure has a first portion under the first epitaxial structure, a second portion under the second epitaxial structure, and a third portion coupled to the first portion to the second portion.

16. A method of manufacturing a semiconductor device, comprising:
forming a first epitaxial structure and a second epitaxial structure on a substrate;
forming a backside interconnection structure under the first epitaxial structure and under the second epitaxial structure, wherein the backside interconnection structure includes a first finger connected to the first epitaxial structure, a second finger connected to the second epitaxial structure, and a main portion connecting the first finger to the second finger; and;
forming a backside conductive layer under the backside interconnection structure.

17. The method of claim 16, further comprising:
forming a conductive structure over the backside interconnection structure; and;
forming a source/drain contact over the first epitaxial structure, the second epitaxial structure, and the conductive structure.

18. The method of claim 16, further comprising:
forming a gate electrode over the substrate, wherein the main portion of the backside interconnection structure is formed under the gate electrode;
removing a portion of the gate electrode over the main portion of the backside interconnection structure; and;
forming a cut feature over the main portion of the backside interconnection structure.

19. The method of claim 16, further comprising:
forming a plurality of fins over the substrate to define trenches;
forming isolation regions within the trenches; and;
removing a portion of the isolation regions to form a first opening, wherein the main portion of the backside interconnection structure is formed within the first opening.

20. The method of claim 19, further comprising:
removing a portion of the plurality of fins to form a second opening under the first epitaxial structure and a third opening under the second epitaxial structure,
wherein the first finger is formed within the second opening, and the second finger is formed within the third opening.
